(19) United States
(12) Patent Application Publication
(10) Pub. No.: US 2014/0246754 A1
(43) Pub. Date: Sep. 4, 2014

(54) METAL-OXIDE-METAL CAPACITOR

(71) Applicant: DONGBU HITEK CO., LTD., Seoul (KR)

(72) Inventor: Su Tae KIM, Suwon-si (KR)

(73) Assignee: DONGBU HITEK CO., LTD., Seoul (KR)

(21) Appl. No.: 13/802,997

(22) Filed: Mar. 14, 2013

(30) Foreign Application Priority Data
Mar. 4, 2013 (KR) 10-2013-0023054

(51) Int. Cl. H01L 49/02

(52) U.S. Cl. CPC H01L 28/87
USPC 257/532; 438/396

(57) ABSTRACT

Provided is a capacitor of a semiconductor device. The capacitor can includes a plurality of parallel lower conductive lines in parallel and a plurality of upper conductive lines on the lower conductive lines. Each lower conductive line can have a line width that is different than that of the upper conductive line adjacent to it.

### CROSS-REFERENCE TO RELATED APPLICATION

This application claims the benefit under 35 U.S.C. §119 of Korean Patent Application No. 10-2013-0023054, filed Mar. 4, 2013, which is hereby incorporated by reference in its entirety.

### BACKGROUND

The present disclosure relates to a method of manufacturing a semiconductor device, and more particularly, to a metal-oxide-metal (MOM) capacitor obtaining more stable capacitance than that having a related art MOM structure with the same area by changing the line width of a conductive line connected to an upper electrode and a lower electrode forming a capacitor on a semiconductor substrate.

In general, a capacitor used in a logic circuit of a semiconductor device is a metal-oxide-metal (MOM) capacitor or a metal-insulator-metal (MIM) capacitor. Because these types of capacitors are independent from bias, unlike a metal-oxide-semiconductor (MOS) capacitor or a junction capacitor, accuracy is very important. In a an MIM capacitor, since the effective area is small and a mask is added during a process, manufacturing costs are increased. In order to compensate for this, an MOM capacitor structure, in which metal is stacked using a related art back end of line (BEOL) process, is typically used. Since the MOM capacitor can be formed smaller than the MIM capacitor in designing a device of less than about 0.13 μm, the capacity per unit area of a capacitor can be increased and high breakdown voltage can be maintained.

In general, a related art MOM capacitor includes a parallel structure in which upper and lower conductive lines are disposed in parallel and a vertical structure in which upper and lower conductive lines are disposed vertically.

FIGS. 1A and 1B are a plan view and a perspective view, respectively, of an MOM capacitor having a parallel structure. Referring to FIG. 1A, the MOM capacitor includes first conductive lines 11a, 11b, and 11c, which are connected to a first electrode 10 and are formed in parallel to each other with the same line width, and second conductive lines 21a, 21b, 21c, which are connected to a second electrode 20 and are formed in parallel to each other with the same line width. The first and second conductive lines have the same line width, and also space line widths between the first and second conductive lines are formed identical to each other.

A third electrode 30, to which a potential of the same polarity as the first electrode 10 is applied, is formed below the first electrode 10, and a fourth electrode 40, to which a potential of the same polarity as the second electrode 20 is applied, is formed below the second electrode 20.

Referring to FIG. 1B, the first 11a, 11b, 11c and second 21a, 21b, and 21c conductive lines have the opposite polarity to the lower third and fourth conductive lines (not labeled) and the same polarity of each conductive line is formed alternately. An oxide layer (not shown) is formed between the first 10 and second 20 electrodes and the third 30 and fourth 40 electrodes, and thus an MOM capacitor is formed, having a structure in which conductive lines are aligned in parallel. However, though such an MOM capacitor structure may increase a capacitance per unit area, it may also cause misalignment, e.g. during fabrication. Therefore, if a space line width between conductive lines changes, the capacitance is drastically decreased.

FIGS. 2A and 2B are a plan view and a perspective view, respectively, of an MOM capacitor having a vertical structure. Referring to FIG. 2A, the upper first 11a, 11b, 11c and second 21a, 21b, and 21c conductive lines are formed vertical to the lower third and fourth conductive lines (not labeled). Although such an MOM capacitor structure can maintain a predetermined capacitance even when misalignment occurs during fabrication and thus a space line width changes between conductive lines, a capacitance per unit area is smaller than that of a parallel structure.

FIG. 3 is a graph illustrating a change in capacitance when misalignment occurs in a related art parallel structure and vertical structure. Referring to FIG. 3, although a vertical structure MOM capacitor can maintain a predetermined capacitance even when misalignment occurs, the capacitance per unit area is relatively small. In the parallel structure MOM capacitor, the capacitance is drastically decreased when misalignment occurs during fabrication or use.

### BRIEF SUMMARY

Embodiments of the subject invention provide a metal-oxide-metal (MOM) capacitor and a method of manufacturing the same, in which a capacitance per unit area is similar to existing MOM capacitors and a predetermined capacitance is maintained even when misalignment occurs during a process (e.g., fabrication or use).

In an embodiment, a capacitor can include a plurality of lower conductive lines in parallel and a plurality of upper conductive lines in parallel and on the lower conductive lines. Each lower conductive line has a line width that is different than that of the upper conductive line adjacent to it, and each upper conductive line has a line width that is different than that of the lower conductive line adjacent to it.

In another embodiment, a method of fabricating a capacitor can include forming a plurality of lower conductive lines in parallel on a semiconductor substrate and forming a plurality of upper conductive lines in parallel on the lower conductive lines. Each lower conductive line has a line width that is different than that of the upper conductive line adjacent to it, and each upper conductive line has a line width that is different than that of the lower conductive line adjacent to it.

### BRIEF DESCRIPTION OF THE DRAWINGS

FIG. 1A is a plan view of a related art metal-oxide-metal (MOM) capacitor having a parallel structure.

FIG. 1B is a perspective view of a related art MOM capacitor having a parallel structure.

FIG. 2A is a plan view of a related art MOM capacitor having a vertical structure.

FIG. 2B is a perspective view of a related art MOM capacitor having a vertical structure.

FIG. 3 is a graph illustrating a change in capacitance when misalignment occurs in related art MOM capacitor having a parallel structure and a related art MOM capacitor having a vertical structure.

FIG. 4A is a perspective view of an MOM capacitor according to an embodiment of the subject invention.

FIG. 4B is a plan view of an MOM capacitor according to an embodiment of the subject invention.

FIG. 5A is an enlarged view of an area A of FIG. 4A and compares to a related art capacitor.

FIG. 5B is a plan view of upper and lower electrodes in the area A of FIG. 4A.

FIG. 5C is a side view of a portion of an MOM capacitor according to an embodiment of the subject invention and a portion of a related art MOM capacitor.

FIG. 6A is a graph of capacitance versus frequency for an MOM capacitor according to an embodiment of the subject invention.

FIG. 6B is a graph of capacitance versus misalignment in an MOM capacitor according to an embodiment of the subject invention.

### DETAILED DESCRIPTION

Reference will now be made in detail to the embodiments of the present disclosure, examples of which are illustrated in the accompanying drawings. The invention may, however, be embodied in many different forms and should not be construed as being limited to the embodiments set forth herein

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

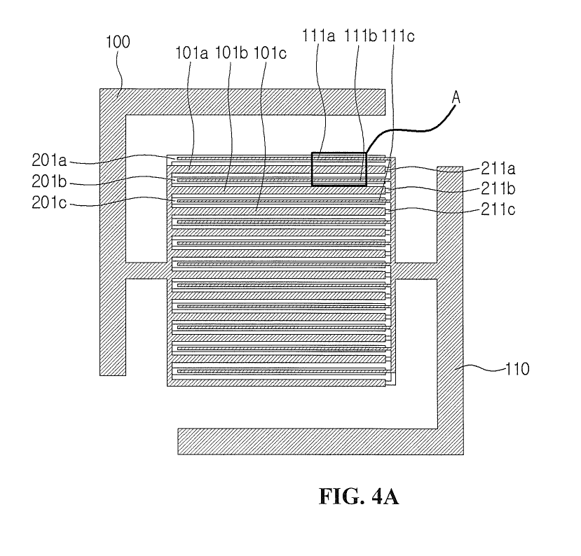

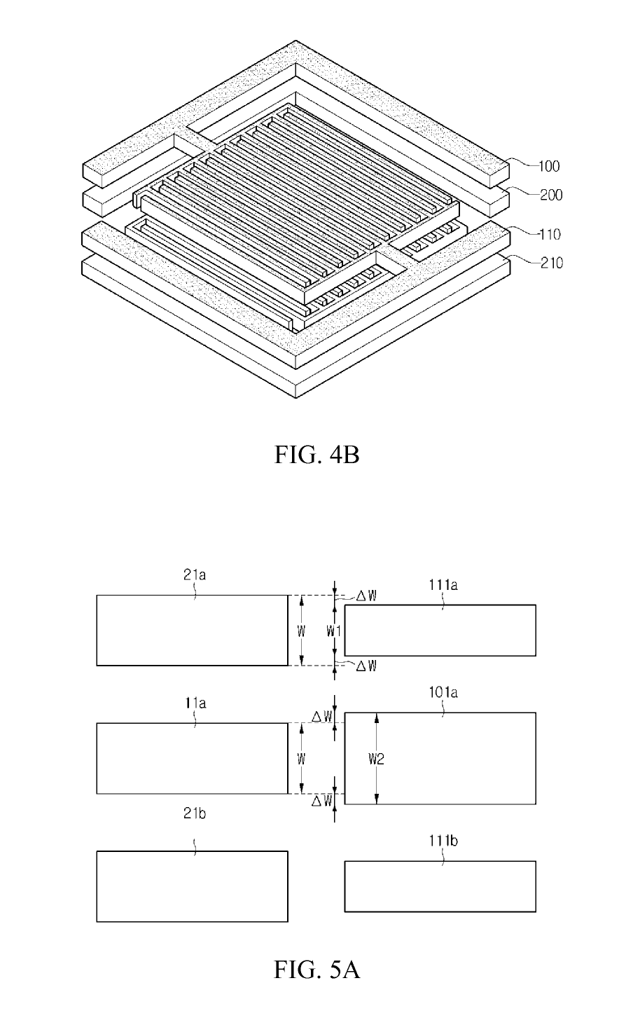

FIGS. 4A and 4B are a plan view and a perspective view, respectively, of a metal-oxide-metal (MOM) capacitor according to an embodiment of the present invention.

Referring to FIG. 4B, an MOM capacitor can include a first electrode 100 and a second electrode 110 (i.e., upper electrodes), and also a third electrode 200 and a fourth electrode 210 (i.e., lower electrodes). The third electrode 200 can be stacked vertically under the first electrode 100, and the fourth electrode 210 can be stacked vertically under the second electrode 110. A potential of the same polarity can be applied to the first electrode 100 and the third electrode 200, and the same potential of the same polarity can be applied to the second electrode 110 and the fourth electrode 210, thereby forming a capacitor having a unit structure.

Referring to FIG. 4A, one side of the first electrode 100 can be connected to a plurality of first upper conductive lines 101a, 101b, and 101c, and one side of the second electrode 110 can be connected to a plurality of second upper conductive lines 111a, 111b, and 111c. The first upper conductive lines 101a, 101b, and 101c of the first electrode 100 and the second upper conductive lines 111a, 111b, and 111c of the second electrode 110 can be stacked vertically (above lower conductive lines), so that they are aligned with first lower conductive lines 201a, 201b, and 201c and second lower conductive lines 211a, 211b, and 211c, with a predetermined width therebetween.

A potential of a polarity different from that of an adjacent conductive line can be applied to each conductive line connected to each electrode. For example, a potential of a polarity different from that of the second 110 and fourth 210 electrodes can be applied to the first electrode 100, and a potential of a polarity different from that of the first 100 and third 200 electrodes can be applied to the second electrode 110.

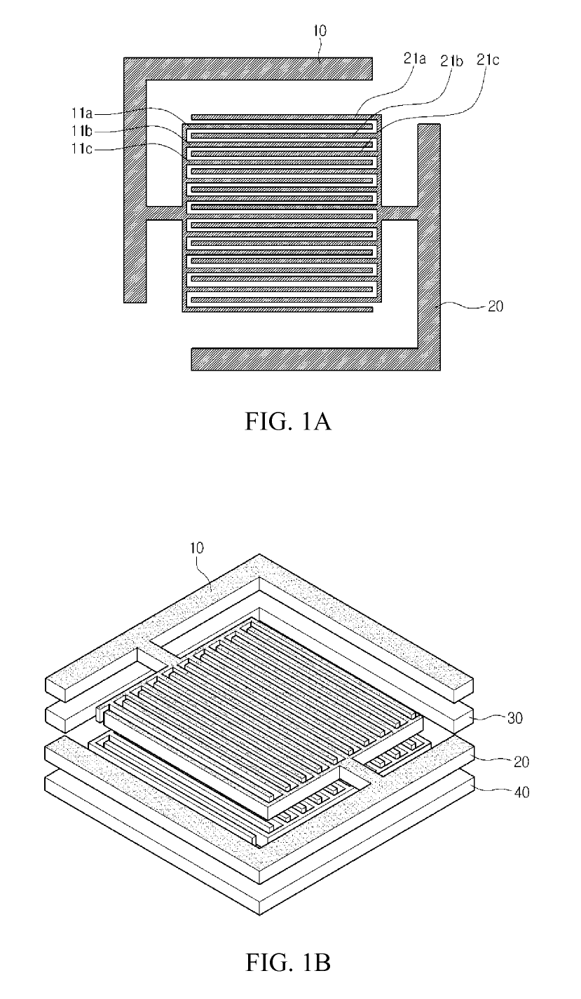

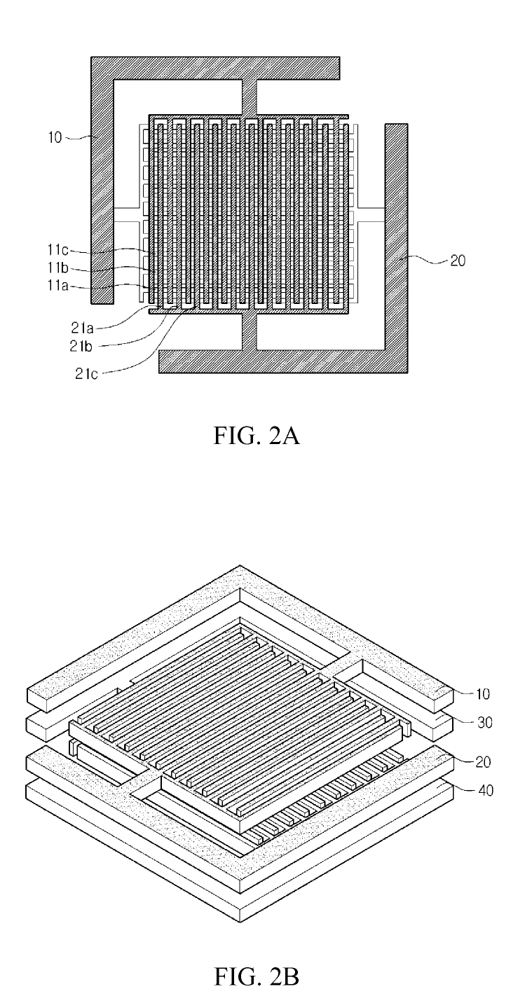

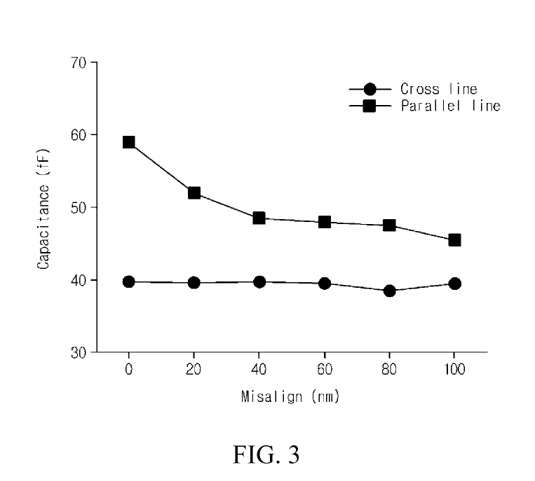

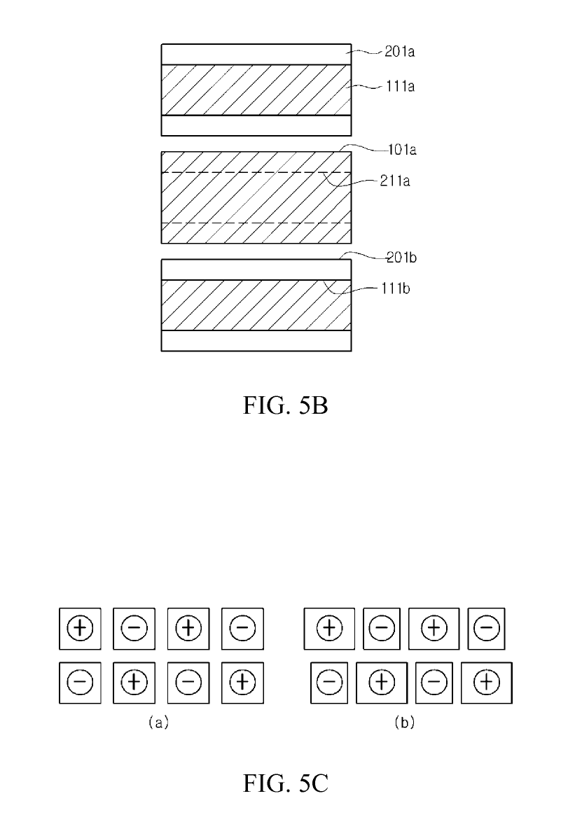

FIG. 5A is an enlarged view of an area A of FIG. 4A (right side of FIG. 5A) and shows the related art MOM capacitor (left side of FIG. 5A) of FIG. 1A having a parallel structure for comparison.

Referring to FIG. 5A, the adjacent conductive lines 21a, 11a, and 21b of the related art MOM capacitor have a width W, are spaced a predetermined distance apart from each other, and form a capacitance by applying different potential.

When the conductive lines in the area A are compared with the related art conductive lines 21a, 11a, and 21b in an area corresponding to the area A, the line widths of the first and second upper conductive lines 111a, 101a, and 111b connected to the first 100 and second 110 electrodes (i.e. the upper electrodes) can be formed by alternately arranging conductive lines having widths, which are increased or decreased by ΔW at both sides compared with the width W of the conductive line of the related art MOM capacitor.

Although only three conductive lines in the enlarged area A are shown in FIG. 5A, conductive lines having a width W2 increased by ΔW at both sides can be continuously arranged connected to the first electrode 100, and conductive lines having the width W1 decreased by ΔW at both sides can be continuously arranged connected to the second electrode 110.

Adjacent conductive lines can be formed to have different line widths by alternately arranging the conductive lines of the first electrode 100 and the conductive lines of the second electrode 110 having a different potential than the first electrode 100.

FIG. 5B is a plan view of upper and lower electrodes in the area A of FIG. 4A. Referring to FIG. 5B, the first electrode 100 and the third electrode 200 are shown from above, and the third electrode is vertically stacked below the first electrode 100.

The third 200 and fourth 210 electrodes can be lower electrodes formed on a semiconductor substrate, and the first 100 and second 110 electrodes can be upper electrodes formed on the lower electrodes. Conductive lines having different line widths in a vertical direction and in a horizontal direction can be arranged to form an MOM capacitor. For example, the conductive lines 111a, 111b of the second electrode 110 can have a different width than that of the conductive lines 101a of the first electrode 100 and a different width than that of the conductive lines 201a, 201b of the third electrode 200. The conductive lines 101a of the first electrode 100 can have a different width than that of the conductive lines 111a, 111b of the second electrode 100 and a different width than that of the conductive lines 211a of the fourth electrode 210. The conductive lines 201a, 201b of the third electrode 200 can have a different width than that of the conductive lines 211a of the fourth electrode 210 and a different width than that of the conductive lines 111a, 111b of the second electrode 110. The conductive lines 211a of the fourth electrode 210 can have a different width than that of the conductive lines 201a, 201b of the third electrode 200 and a different width than that of the conductive lines 101a of the first electrode 100. That is, a conductive line can have a width that is larger or smaller than that of an adjacent conductive line and can have a different potential applied to it than a potential applied to an adjacent conductive line.

In an embodiment, the conductive lines 101a of the first electrode 100 can have a width that is the same or approximately same as the width of the conductive lines 201a, 201b of the third electrode 200, and the conductive lines 111a, 111b of the second electrode 110 can have a width that is the same or approximately same as the width of the conductive lines 211a of the fourth electrode 210.

FIG. 5C includes a side view of FIG. 5A as well as a side view of a related art MOM capacitor. FIG. 5C(a) represents a related art structure, and FIG. 5C(b) is a side view of FIG. 5B. Four conductive lines are shown for exemplary purposes only, and this depiction of four conductive lines should not be construed as limiting.

Referring to FIG. 5C(a), in a related art structure, conductive lines have the same line width and form a capacitance between the upper and lower conductive lines.

However, referring to FIG. 5C(b), according to an embodiment of the subject invention, the line widths alternate such that the line width of adjacent conductive lines, both vertically and horizontally are different. For example, the top left conductive line pictured is wider, by a predetermined amount, than the conductive line immediately below it and immediately to its right. Similarly, the top right conductive line pictured is narrower, by a predetermined amount, than the conductive line immediately below it and immediately to its left. Since the quantity of upper and lower conductive lines in the capacitor according to an embodiment of the subject invention can be the same as that in the related art capacitor, a capacitance similar to that of the related art capacitor may be maintained.

The conductive lines connected to an upper electrode (e.g., the first electrode 100 or the second electrode 110) can be aligned over the conductive lines of a lower electrode (e.g., the third electrode 200 or the fourth electrode 210) so as to form a capacitance. Even if the upper electrode (e.g., the first electrode 100 or the second electrode 110) and the lower electrode over which it is aligned (e.g., the third electrode 200 or the fourth electrode 210) are misaligned in a horizontal direction, constant capacitance can be maintained because the widths of the conductive lines of the upper electrode and the widths of the conductive lines of the lower electrode over which it is aligned are different.

For example, the conductive lines connected to the first electrode 100 can be aligned over the conductive lines of the fourth electrode 210 so as to form a capacitance. Even if the first electrode 100 and the fourth electrode 210 are misaligned in a horizontal direction, constant capacitance can be maintained because the widths of the conductive lines 101a of the first electrode 100 and the widths of the conductive lines 211a of the fourth electrode 210 are different.

As another example, the conductive lines connected to the second electrode 110 can aligned over the conductive lines of the third electrode 200 so as to form a capacitance. Even if the second electrode 110 and the third electrode 200 are misaligned in a horizontal direction, constant capacitance can be maintained because the widths of the conductive lines 111a, 111b of the second electrode 110 and the widths of the conductive lines 201a, 201b of the third electrode 200 are different.

In an embodiment of the present invention, a value of ΔW can be about 100 nm (e.g., in 0.18 μm technology). For example the line width W1 of a conductive line, which is smaller than a related art conductive line, can be about W−200 nm, and the line width W2 of a conductive line, which is larger than a related art conductive line, can be about W+200 nm.

In an embodiment, a value of ΔW can be about 60 nm (e.g., in 0.13 μm technology). For example, the line width W1 of a conductive line, which is smaller than a related art conductive line, can be about W−120 nm, and the line width W2 of a conductive line, which is larger than a related art conductive line, can be about W+120 nm.

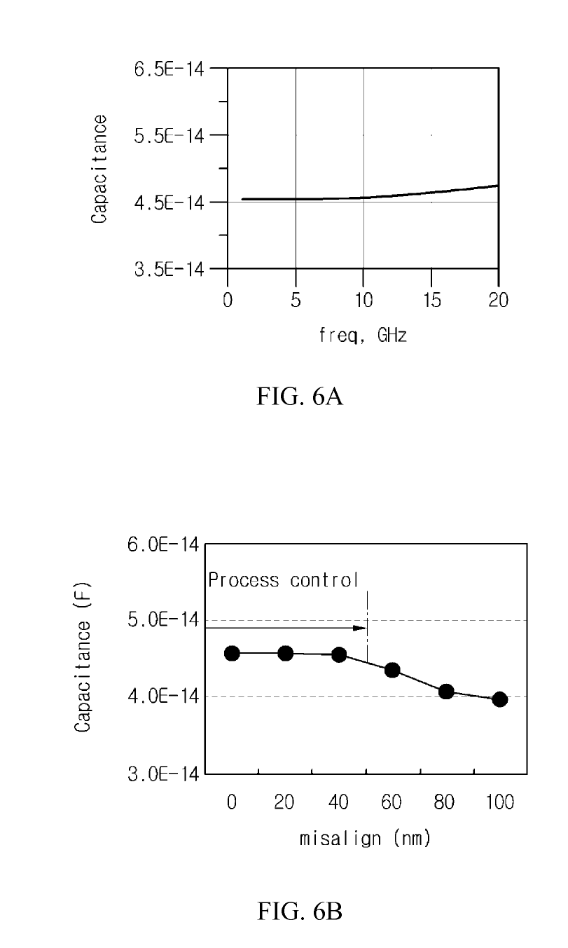

FIG. 6A is a graph of capacitance versus frequency for an MOM capacitor according to an embodiment of the present invention. Referring to FIG. 6A, it is confirmed that a capacitance measured from a circuit performing a high frequency operation of about 5 GHz to about 15 GHz maintains a value of about 4.5E-14 F, and this is similar to a level of a capacitance of a unit area for a related art capacitor having a parallel structure.

FIG. 6B is a graph illustrating a change in capacitance when misalignment occurs in an MOM capacitor according to an embodiment of the present invention.

Referring to FIG. 6B, when misalignment occurs in a level of less than about 40 nm, a capacitance maintains a predetermined value, and when misalignment occurs in a level of more than about 40 nm, a capacitance is reduced to a predetermined level.

Thus, while capacitance is drastically decreased when misalignment occurs in a related structure, an MOM capacitor according to embodiments of the present invention can obtain constant capacitance even when misalignment occurs (e.g., during fabrication or use). That is, stable semiconductor device manufacturing processes are possible by obtaining a 40 nm margin of a process for aligning the upper and lower electrodes of a capacitor.

Additionally, a capacitance per unit area is obtained similar to that of a related art MOM capacitor, so that a semiconductor device for high speed and high frequency operations may be manufactured.

According to embodiments of the present invention, a predetermined capacitance is obtained when misalignment occurs resulting from changing the line widths and spaces of conductive lines of an MOM capacitor on a semiconductor substrate, so that the stability of a semiconductor device may be obtained.

Moreover, a capacitance per unit area is obtained similar to that of a related art MOM capacitor, so that a semiconductor device for high speed and high frequency operations may be manufactured.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

1. A metal-oxide-metal (MOM) capacitor, comprising:
a plurality of lower conductive lines formed in parallel with one another at a first horizontal level; and
a plurality of upper conductive lines formed in parallel with one another at a second horizontal level and vertically on the lower conductive lines;
wherein each lower conductive line has a line width that is different from that of the upper conductive line adjacent to it;
wherein each upper conductive line has a line width that is different from that of the lower conductive line adjacent to it;
wherein a line width of each conductive line is different from that of any adjacent conductive line at the same horizontal level; and
wherein each conductive line is not directly connected with any adjacent conductive line.

2. The MOM capacitor according to claim 1, wherein the plurality of upper conducive lines comprises:
a plurality of first upper conductive lines connected to a first electrode; and
a plurality of second upper conductive lines connected to a second electrode.

3. The MOM capacitor according to claim 2, wherein the first upper conductive lines and the second upper conductive lines are formed alternately, such that each first upper conductive line of the plurality of first upper conductive lines is adjacent to a second upper conductive line and each second upper conductive line of the plurality of second upper conductive lines is adjacent to a first upper conductive line.

4. The MOM capacitor according to claim 3, wherein an interval between each first upper conductive line and the adjacent second upper conductive line is constant.

5. The MOM capacitor according to claim 2, wherein each first upper conductive line of the plurality of first upper conductive lines has a line width that is the same as that of all other first upper conductive lines, and wherein each second upper conductive line of the plurality of second upper conductive lines has a line width that is the same as that of all other second upper conductive lines.

6. The MOM capacitor according to claim 5, wherein the line width of each first upper conductive line is different from that of each second upper conductive line.

7. The MOM capacitor according to claim 2, wherein the plurality of lower conductive lines comprises:
a plurality of first lower conductive lines connected to a third electrode; and
a plurality of second lower conductive lines connected to a fourth electrode.

8. The MOM capacitor according to claim 7, wherein the first lower conductive lines and the second lower conductive lines are formed alternately, such that each first lower conductive line of the plurality of first lower conductive lines is adjacent to a second lower conductive line and each lower conductive line of the plurality of second lower conductive lines is adjacent to a first lower conductive line.

9. The MOM capacitor according to claim 8, wherein an interval between each first lower conductive line and the adjacent second lower conductive line is constant.

10. The MOM capacitor according to claim 7, wherein each first lower conductive line connected to the third electrode is vertically adjacent to a second upper conductive line connected to the second electrode, and wherein each second lower conductive line connected to the fourth electrode is vertically adjacent to a first upper conductive line connected to the first electrode.

11. The MOM capacitor according to claim 7, wherein each first lower conductive line connected to the third electrode has a line width that is the same as that of each first upper conductive line connected to the first electrode, and wherein each second lower conductive line connected to the fourth electrode has a line width that is the same as that of each second upper conductive line connected to the second electrode.

12. The MOM capacitor according to claim 11, wherein a potential of the same polarity is applied to both the first electrode and the third electrode.

13. The MOM capacitor according to claim 7, wherein each first lower conductive line of the plurality of first lower conductive lines has a line width that is the same as that of all other first lower conductive lines, and wherein each second lower conductive line of the plurality of second lower conductive lines has a line width that is the same as that of all other second lower conductive lines.

14. The MOM capacitor according to claim 13, wherein the line width of each first lower conductive line is different from that of each second lower conductive line.

15. The MOM capacitor according to claim 1, wherein the plurality of lower conductive lines are spaced apart from each other by an insulating material.

16. The MOM capacitor according to claim 1, wherein the lower conductive lines and the upper conductive lines are spaced apart from each other by an insulating material.

17. The MOM capacitor according to claim 1, wherein the plurality of lower conductive lines and the plurality of upper conductive lines are parallel to each other.

18. The MOM capacitor according to claim 1,
wherein the plurality of upper conducive lines comprises:
a plurality of first upper conductive lines connected to a first electrode; and
a plurality of second upper conductive lines connected to a second electrode,
wherein the first upper conductive lines and the second upper conductive lines are formed alternately, such that each first upper conductive line of the plurality of first upper conductive lines is adjacent to a second upper conductive line and each second upper conductive line of the plurality of second upper conductive lines is adjacent to a first upper conductive line,
wherein an interval between each first upper conductive line and the adjacent second upper conductive line is constant,
wherein each first upper conductive line of the plurality of first upper conductive lines has a line width that is the same as that of all other first upper conductive lines, and wherein each second upper conductive line of the plurality of second upper conductive lines has a line width that is the same as that of all other second upper conductive lines,
wherein the line width of each first upper conductive line is different from that of each second upper conductive line,
wherein the plurality of lower conductive lines comprises:
a plurality of first lower conductive lines connected to a third electrode; and
a plurality of second lower conductive lines connected to a fourth electrode,
wherein the first lower conductive lines and the second lower conductive lines are formed alternately, such that each first lower conductive line of the plurality of first lower conductive lines is adjacent to a second lower conductive line and each lower conductive line of the plurality of second lower conductive lines is adjacent to a first lower conductive line,
wherein an interval between each first lower conductive line and the adjacent second lower conductive line is constant,
wherein each first lower conductive line connected to the third electrode is vertically adjacent to a second upper conductive line connected to the second electrode, and wherein each second lower conductive line connected to the fourth electrode is vertically adjacent to a first upper conductive line connected to the first electrode,
wherein each first lower conductive line of the plurality of first lower conductive lines has a line width that is the same as that of all other first lower conductive lines, and wherein each second lower conductive line of the plurality of second lower conductive lines has a line width that is the same as that of all other second lower conductive lines,
wherein the line width of each first lower conductive line is different from that of each second lower conductive line, and
wherein each conductive line is not directly connected with any adjacent conductive line.

19. A method of fabricating a metal-oxide-metal (MOM) capacitor, comprising:
forming a plurality of lower conductive lines in parallel with one another at a first horizontal level on a semiconductor substrate; and
forming a plurality of upper conductive lines in parallel with one another at a second horizontal level and vertically on the lower conductive lines,
wherein each lower conductive line has a line width that is different from that of the upper conductive line adjacent to it,
wherein each upper conductive line has a line width that is different from that of the lower conductive line adjacent to it,
wherein a line width of each conductive line is different from that of any adjacent conductive line at the same horizontal level; and
wherein each conductive line is not directly connected with any adjacent conductive line.

20. The method according to claim 19,
wherein forming the plurality of upper conducive lines comprises:
forming a plurality of first upper conductive lines connected to a first electrode; and
forming a plurality of second upper conductive lines connected to a second electrode,
wherein the first upper conductive lines and the second upper conductive lines are formed alternately, such that each first upper conductive line of the plurality of first upper conductive lines is adjacent to a second upper conductive line and each second upper conductive line of the plurality of second upper conductive lines is adjacent to a first upper conductive line,
wherein each first upper conductive line of the plurality of first upper conductive lines has a line width that is the same as that of all other first upper conductive lines, and wherein each second upper conductive line of the plurality of second upper conductive lines has a line width that is the same as that of all other second upper conductive lines,
wherein the line width of each first upper conductive line is different from that of each second upper conductive line,
wherein forming the plurality of lower conductive lines comprises:
forming a plurality of first lower conductive lines connected to a third electrode; and
forming a plurality of second lower conductive lines connected to a fourth electrode,
wherein the first lower conductive lines and the second lower conductive lines are formed alternately, such that each first lower conductive line of the plurality of first lower conductive lines is adjacent to a second lower conductive line and each lower conductive line of the plurality of second lower conductive lines is adjacent to a first lower conductive line,
wherein each first lower conductive line connected to the third electrode is vertically adjacent to a second upper conductive line connected to the second electrode, and wherein each second lower conductive line connected to the fourth electrode is vertically adjacent to a first upper conductive line connected to the first electrode,
wherein each first lower conductive line of the plurality of first lower conductive lines has a line width that is the same as that of all other first lower conductive lines, and wherein each second lower conductive line of the plurality of second lower conductive lines has a line width that is the same as that of all other second lower conductive lines, and
wherein the line width of each first lower conductive line is different from that of each second lower conductive line.
